(19) United States
(12) Patent Application Publication
(10) Pub. No.: US 2025/0331315 A1
(43) Pub. Date: Oct. 23, 2025

(54) FRONT-FACE SUBSTRATE FOR A SOLAR MODULE

(71) Applicant: Schott AG, Mainz (DE)

(72) Inventors: Lutz Gaeckle, Göttingen (DE); Alexander Glacki, Hannover (DE); Tilmann Goetze, Einbeck (DE)

(73) Assignee: Schott AG, Mainz (DE)

(21) Appl. No.: 18/854,841

(22) PCT Filed: Mar. 14, 2023
(86) PCT No.: PCT/EP2023/056461

§ 371 Date: Oct. 7, 2024

(30) Foreign Application Priority Data
Apr. 7, 2022 (DE) 10 2022 108 483.3
Mar. 14, 2023 (WO) PCTEP2023056461

(51) Int. Cl. H10F 19/80

(52) U.S. Cl. CPC H10F 19/804

(57) ABSTRACT

The invention relates to a front-face substrate for a solar module, in particular for mobile applications, for example mobile devices, means of transportation, or manned or unmanned flying objects, wherein the front-face substrate has a weight per unit area of under 500 g/m² and comprises a material which has a transmission curve T(λ) for a reference thickness of 100 μm, said transmission curve forming a transition from a lower transmission T_{low} to an upper transmission Tᵤₚ and having a transitional transmission Tₜᵣ therebetween of 50% in a wavelength range of 302 nm to 322 nm.

### CROSS-REFERENCE TO RELATED APPLICATIONS

This application is a national stage entry under 35 U.S.C. § 371 of International Patent Application No. PCT/EP2023/056461 entitled “FRONT-FACE SUBSTRATE FOR A SOLAR MODULE,” filed on Mar. 14, 2023, which is incorporated in its entirety herein by reference. International Patent Application No. PCT/EP2023/056461 claims priority to German Patent Application No. 10 2022 108 483.3 filed on Apr. 7, 2022, which is incorporated in its entirety herein by reference.

### BACKGROUND OF THE INVENTION

### 1. Technical Field of the Invention

The invention relates to a frontside substrate for a solar module, especially for mobile applications.

### 2. Description of the Related Art

Solar modules are frequently constructed with a backside element, which can also be referred to as back panel, a frontside element, which can also be referred to as cover or frontside substrate, and the solar cell itself, which is disposed between the back panel and the cover for protection from unwanted influences and to increase stability.

The individual components of the solar module may be optimized with regard to the desired application. The frontside substrate may be of particular significance here, in that it should be transparent in each case to the relevant radiation as well.

### SUMMARY OF THE INVENTION

It is the object of the present invention to provide a frontside substrate which is optimized for various kinds of mobile applications and is accordingly usable in a versatile manner, especially for mobile devices, modes of transport, modes of transportation or manned or unmanned flying objects, is simultaneously producible at minimum cost, and also permits construction of the solar module at minimum expense or a reduction in the costs of further components of the solar module. Another aspect of the object is high solarization resistance.

The object is achieved by disclosure of a frontside substrate for a solar module, which has a surface weight of below 500 g/m² and which comprises a material which, at a reference thickness of 100 μm, has a transmittance curve T(λ) that forms a transition from a lower transmittance T_{low} to an upper transmittance Tᵤₚ and has an intervening intermediate transmittance Tₜᵣ=50% in a wavelength range from 302 nm to 322 nm.

The frontside substrate is intended especially for mobile applications, for example mobile devices, modes of transport, modes of transportation or manned or unmanned flying objects.

With a surface weight of below 500 g/m², the frontside substrate can contribute to a reduction in weight of the solar module, which may be advantageous to some mobile applications. A solar module of reduced weight may especially be advantageous for manned or unmanned flying objects, for example for passenger aircraft, gliders, drones, possibly even rockets, satellites, etc., and also for vehicles or for mobile devices.

In some of these applications, for example in the case of drones or mobile devices, it is additionally possible to save battery weight if power can be supplied partly via a solar module.

In some applications, especially in the case of aircraft or flying objects, there may additionally be a high level of UV radiation or even particle radiation.

Since the frontside substrate, at a reference thickness of 100 μm, has a transmittance curve T(λ) that forms a transition from a lower transmittance Tow to an upper transmittance Tᵤₚ and has an intervening intermediate transmittance Tₜᵣ=50% in a wavelength range from 302 nm to 322 nm, it is especially possible to enable a protective effect for the solar cell for a short-wave range. In particular, the transmittance curve T(λ) may also assure a protective effect for applications in the case of aircraft or flying objects where there can be a high level of UV radiation. What is thus enabled overall is versatile usability for a wide variety of different mobile applications.

Because the transmittance curve T(λ) enables a protective effect specifically with respect to short-wave radiation, it is sometimes possible to dispense with further filters as components of the solar module and hence in turn to achieve a reduction in weight and in costs.

It may be the case that it is additionally possible to use less costly adhesive materials in solar modules comprising an adhesive layer for bonding of the frontside substrate to the solar cell or for lamination of the solar cell.

It should be mentioned that specifically the combination of the surface weight mentioned and the intermediate transmittance that defines a relatively high UV edge interact in such a way as savings in the material of other components, for example in the adhesive, of the solar module become possible and the total weight thereof can be reduced.

In principle, the abovementioned transmittance curve T(λ) relates to a reference thickness of 100 μm. Conversion of another thickness is possible in that a measurement of thickness, a measurement of transmittance and a measurement of dispersion are conducted for the glass of different thickness, i.e. a determination of the wavelength-dependent refractive index, which are used to calculate internal transmittance and coefficient of absorption. Subsequently, it is possible to calculate internal transmittance for the reference thickness of 100 μm and, taking account of the reflection losses, transmittance for the reference thickness of 100 μm.

In one development of the invention, it may be the case that the frontside substrate has a surface weight of below 400 g/m², preferably of below 300 g/m², more preferably of below 250 g/m², yet more preferably of below 200 g/m². A surface weight of below 275 g/m² may likewise be preferred.

In addition, in one development, it may be the case that the intermediate transmittance Tₜᵣ=50% is in a wavelength range from 304 nm to 318 nm, preferably in a wavelength range from 306 nm to 314 nm, more preferably in a wavelength range from 308 nm to 312 nm.

The frontside substrate may especially have a thickness of less than 150 μm, preferably of less than 100 μm, more preferably of less than 80 μm, even more preferably of less than 60 μm, even more preferably of less than 40 μm.

The frontside substrate may thus especially take the form of an ultrathin glass (UTG).

It may preferably be the case that the transmittance curve T(λ) falls below a value of Tₜᵣ=10% at a wavelength in a wavelength range from 288 nm to 312 nm, preferably in a wavelength range from 294 nm to 306 nm, more preferably in a wavelength range from 298 to 302 nm.

It may further preferably be the case that the transmittance curve T(λ) rises above a value of Tₜᵣ=90% at a wavelength in a wavelength range from 322 nm to 400 nm, preferably in a wavelength range from 330 nm to 380 nm, more preferably in a wavelength range from 335 to 360 nm.

In principle, this can achieve the effect that transmittance in the working region of typical solar cells is at a maximum. For example, transmittance for VIS and NIR may be greater than or equal to 91%. High transmittance for VIS and NIR is particularly advantageous especially for mobile applications at relatively great height, for example in the case of aircraft or flying objects. This is especially true in association with the abovementioned intermediate transmittance which permits a relatively high UV edge for shorter-wave radiation.

In one development, the lower transmittance T_{low} may be less than 5%, preferably less than 2.5%, more preferably less than 1%.

Alternatively or additionally, the upper transmittance Tᵤₚ may be greater than 858, preferably greater than 87.5%, more preferably greater than 90%.

In one embodiment, it may be the case that the lower transmittance T_{low} is at a wavelength of at least 250 nm, preferably at a wavelength of at least 275 nm, more preferably at a wavelength of at least 285 nm, yet more preferably at a wavelength of at least 290 nm.

Alternatively or additionally, in one embodiment, it may be the case that the upper transmittance Tᵤₚ is at a wavelength of at most 375 nm, preferably at a wavelength of at most 350 nm, more preferably at a wavelength of at most 340 nm, yet more preferably at most 335 nm.

For example, the transmittance curve at at least one point may have a slope of 2.8 percentage points/nm, especially at a point between the lower transmittance T_{low} and the upper transmittance Tᵤₚ, preferably between a transmittance of 10% and 80%.

Through choice of a suitable solarization resistance, the glass of a frontside substrate may retain maximum stability of transmittance under UV irradiation, such that the transmittance curve, especially the intermediate transmittance, is shifted to a minimum degree.

For example, it may be the case that the transmittance curve, especially the intermediate transmittance Tₜᵣ=50%, after irradiation for 7 hours with light in the wavelength range from 250 nm to 600 nm, especially with a spectrum according to FIG. 5, has a shift of less than 5.0 nm, preferably a shift of less than 3.0 nm, more preferably a shift of less than 1.0 nm, yet more preferably a shift of less than 0.5 nm.

Alternatively or additionally, in a further definition, it may be the case that the transmittance curve, especially the intermediate transmittance Tₜᵣ=50%, after irradiation for 100 hours with UV-A light at 210 W/m², UV-B light at 170 W/m² and UV-C light at 250 W/m², especially with a spectrum according to FIG. 6, has a shift of less than 5.0 nm, preferably a shift of less than 3.0 nm, more preferably a shift of less than 1.0 nm, yet more preferably a shift of less than 0.5 nm.

In one embodiment, it may be the case that the material of the frontside substrate comprises a glass, especially a borosilicate glass having a glass composition that does not contain Li₂O or contains Li₂O with a proportion of less than 50 ppm, preferably of less than 10 ppm, more preferably of less than 5 ppm, yet more preferably of less than 1 ppm. Li₂O is a component in the glass that can diffuse relatively easily, and hence can damage semiconductors such as solar cells.

It may further be the case that the glass composition contains no CaO or contains Cao with a proportion of less than 50 ppm, preferably of less than 10 ppm, more preferably of less than 5 ppm, yet more preferably of less than 1 ppm. This may especially be desired or advantageous with regard to the modulus of elasticity or the flexibility of the glass.

It may further be the case that the glass composition contains no MgO or contains MgO with a proportion of less than 50 ppm, preferably of less than 10 ppm, more preferably of less than 5 ppm, yet more preferably of less than 1 ppm. This may especially be desired or advantageous with regard to the modulus of elasticity or the flexibility of the glass.

It may further be the case that the glass composition contains no BaO or contains Bao with a proportion of less than 50 ppm, preferably of less than 10 ppm, more preferably of less than 5 ppm, yet more preferably of less than 1 ppm.

It may further be the case that the glass composition contains no SrO or contains SrO with a proportion of less than 50 ppm, preferably of less than 10 ppm, more preferably of less than 5 ppm, yet more preferably of less than 1 ppm.

It may further be the case that the glass composition contains no antimony (Sb) or contains antimony (Sb) with a proportion of less than 50 ppm, preferably of less than 10 ppm, more preferably of less than 5 ppm, yet more preferably of less than 1 ppm. This may be desired or advantageous especially with regard to toxicity or occupational safety. Moreover, polyvalent ions such as Sb₂O₃, depending on the glass matrix, may sometimes have an adverse effect on solarization resistance.

It may further be the case that the glass composition contains no arsenic (As) or contains arsenic (As) with a proportion of less than 50 ppm, preferably of less than 10 ppm, more preferably of less than 5 ppm, yet more preferably of less than 1 ppm. This may be desired or advantageous especially with regard to toxicity or occupational safety. Moreover, polyvalent ions such as As₂O₃, depending on the glass matrix, may sometimes have an adverse effect on solarization resistance.

In one embodiment, it may be the case that the material of the frontside substrate comprises a glass, especially a borosilicate glass having a glass composition that contains no cerium oxide or contains cerium oxide with a proportion of less than 500 ppm. This may be desired or advantageous especially with regard to the position of the intermediate transmittance and/or the efficiency in the VIS-NIR transmittance spectrum. In particular, higher transmittance may be achievable for blue light.

In particular, depending on the application, it is possible to consciously dispense with cerium oxide in order to enable a further reduction in costs even though cerium oxide can in principle also be advantageous with regard to solarization resistance. This may be a particularly advantageous compromise in mobile applications, especially in the case of time-limited use.

Cerium oxide is an element which can firstly counteract solarization of the glass and can secondly reduce transmittance for blue light. It has been found that, surprisingly, sufficient solarization resistance to UV radiation can also be achieved with a glass that contains no cerium oxide or contains cerium oxide with a proportion of less than 500 ppm.

In one embodiment, it may be the case that the material of the frontside substrate comprises a glass having a glass composition that contains TiO₂ in a proportion of 0.5 to 10 percent by weight, preferably 2 to 8 percent by weight, more preferably 3 to 5 percent by weight.

It may further be the case that the glass composition contains Al₂O₃ in a proportion of 0 to 15 percent by weight, preferably 3.5 to 15 percent by weight, more preferably 3.5 to 4.5 percent by weight.

It may further be the case that the glass composition contains SiO₂ in a proportion of 30 to 80 percent by weight, preferably 50 to 75 percent by weight, more preferably 60 to 70 percent by weight.

It may further be the case that the glass composition contains B₂O₃ in a proportion of 3 to 20 percent by weight, preferably 5.5 to 9.5 percent by weight, more preferably 7.5 to 8.8 percent by weight.

The material of the frontside substrate may have a density of less than 3.25 g/cm³, preferably less than 3 g/cm³, more preferably less than 2.75 g/cm³.

In one embodiment, the frontside substrate may have a modulus of elasticity higher than 68 GPa, preferably higher than 70 GPa, more preferably higher than 72 GPa, and/or a modulus of elasticity lower than 78 GPa, preferably lower than 76 GPa, more preferably lower than 74 GPa.

The material of the frontside substrate may have a coefficient of thermal expansion in a temperature range from 20° C. to 300° C. which is greater than 4×10⁻⁶ K⁻¹, preferably greater than 5×10⁻⁶ K⁻¹, more preferably greater than 6×10⁻⁶ K⁻¹, yet more preferably greater than 7×10⁻⁶ K⁻¹.

The coefficient of thermal expansion can thus be matched, for example, in an advantageous manner to that of a solar module, especially to that of an adhesive layer, of a solar cell and/or of a backside element, or vice versa. For example, it is possible to consider cost savings in a backside element via less costly materials.

The frontside substrate may have a dimension of greater than 35 cm, preferably greater than 45 cm, more preferably greater than 60 cm, and/or a dimension, especially a second, for example orthogonal, dimension, of greater than 65 cm, preferably greater than 75 cm, more preferably greater than 90 cm. A frontside substrate having dimensions of 55×80 cm is possible, for example.

One advantage of the relatively large dimensions mentioned is that the solar cells in a solar module are coverable by a minimum number of frontside substrates, such that it is possible to reduce complexity of handling and bonding. The relatively large dimensions mentioned may in particular be achievable in an industrially standard and inexpensive manner only in association with the abovementioned glass thicknesses, e.g. UTG.

The invention further relates to a frontside unit for a solar module, especially for mobile applications, for example mobile devices, modes of transport, modes of transportation or manned or unmanned flying objects, comprising a frontside substrate as described above and an adhesive layer bonded two-dimensionally atop the frontside substrate.

The invention further relates to a solar module, especially for mobile applications, for example mobile devices, modes of transport, modes of transportation or manned or unmanned flying objects, comprising a frontside substrate as described above, preferably a backside element, especially in the form of a module frame, a solar cell, preferably disposed between the backside element and the frontside substrate, and an adhesive layer that bonds the frontside substrate to the solar cell.

An adhesive layer may comprise at least one of the following materials: butyl polymer, EVA, PVB, SMP (silyl-modified polymer), transparent silicone.

The invention further relates to the use of a frontside substrate as described above or of a frontside unit as described above for a solar module, especially for mobile applications, for example mobile devices, modes of transport, modes of transportation or manned or unmanned flying objects.

The invention finally also relates to the use of a solar module as described above for mobile applications, for example mobile devices, modes of transport, modes of transportation or manned or unmanned flying objects.

### BRIEF DESCRIPTION OF THE DRAWINGS

The invention is described in detail hereinafter with reference to the figures. The figures show:

FIG. 1: a schematic diagram in a top view of a frontside substrate,

FIG. 2: a schematic diagram in section view of a frontside unit with a frontside substrate and an adhesive layer,

FIG. 3: a schematic diagram in a section view of a solar module,

FIG. 4: a graph of the transmittance curve of a frontside substrate with a thickness of 100 μm before and after solarization irradiation with a radiation source having an energy distribution according to FIG. 6,

FIG. 5: a graph of a relative spectral energy distribution of a radiation source for examination of solarization resistance,

FIG. 6: a graph of a relative spectral energy distribution of a further radiation source for examination of solarization resistance.

### DETAILED DESCRIPTION OF THE INVENTION

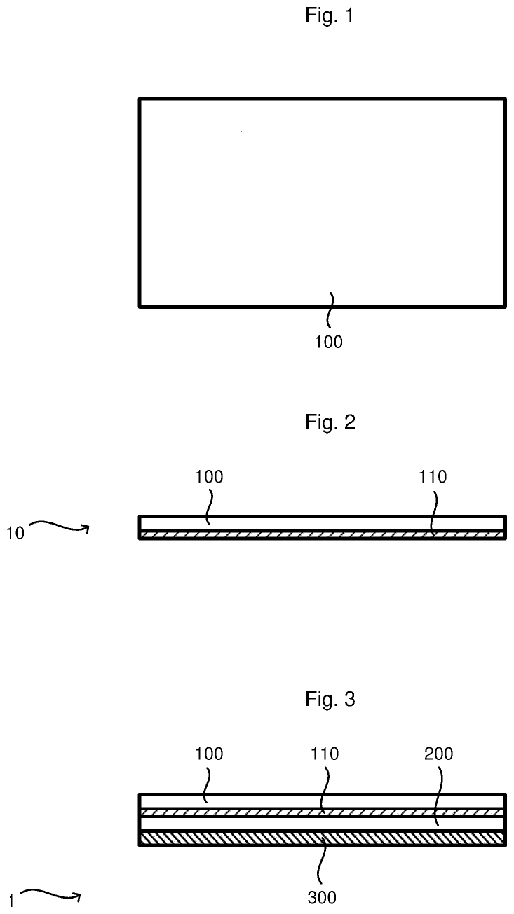

FIGS. 1-3 show a frontside substrate 100 (FIG. 1), a frontside unit 10 comprising a frontside substrate 100 and an adhesive layer 110 applied two-dimensionally on one side of the frontside substrate 100 (FIG. 2), and a solar module 1 comprising a solar cell 200 disposed between a frontside substrate 100 (or a frontside unit 10) and a backside element 300, wherein the frontside unit 100 is two-dimensionally bonded to a surface of the solar cell 200 by the adhesive layer 110 (FIG. 3).

The frontside substrate here has a surface weight of below 500 g/m², for example a surface weight of 251 g/m², and a thickness of 100 μm. Moreover, the frontside substrate has, for example, a glass composition containing the following components in percent by weight:

| | |
|---|---|
| SiO₂ | 63.8-64.8 |
| Al₂O₃ | 3.2-4.4 |
| B₂O₃ | 7.4-8.6 |
| Na₂O | 5.5-6.7 |
| K₂O | 6.3-7.3 |
| ZnO | 5.2-6.7 |
| TiO₂ | 3.6-4.6 |
| Sb₂O₃ | 0.4-1.2 |
| Cl | 0.05-1.3 |

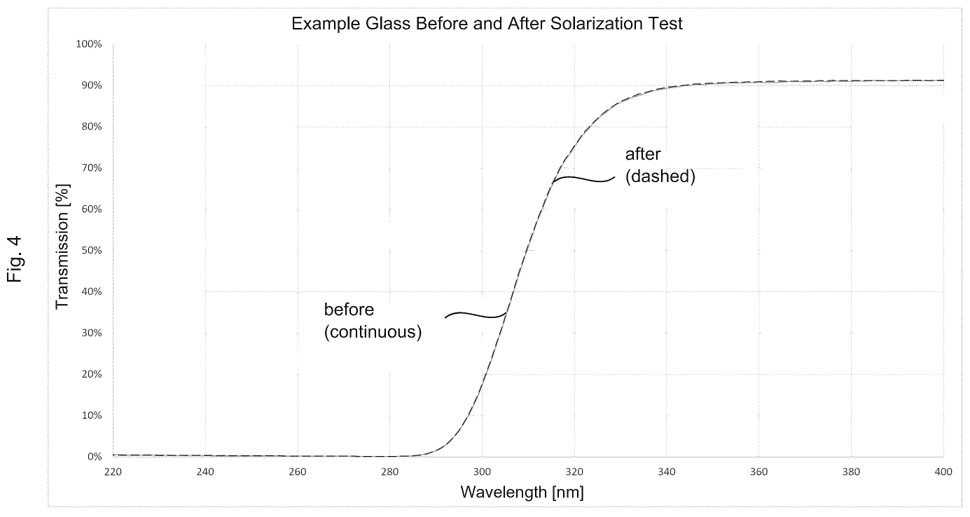

FIG. 4 shows transmittance curves of such an illustrative frontside substrate having a thickness of 100 μm before and after a solarization test in which the substrate was irradiated for 100 hours with UV-A light at 210 W/m², UV-B light at 170 W/m² and UV-C light at 250 W/m². The irradiation spectrum is shown in FIG. 6. It is found that the transmittance curve and the intermediate transmittance Tₜᵣ=50% have a shift of less than 1 nm.

A further illustrative glass composition comprises the following proportions in percent by weight, where contamination with iron is in the region of ≤50 ppm:

| | |
|---|---|
| SiO₂ | 63.4-64.4 |
| Al₂O₃ | 3.3-4.4 |
| B₂O₃ | 7.2-8.6 |
| Na₂O | 5.7-6.7 |
| K₂O | 6.4-7.4 |
| ZnO | 4.8-6.5 |
| TiO₂ | 3.2-4.3 |
| Se | 0.005-0.1 |

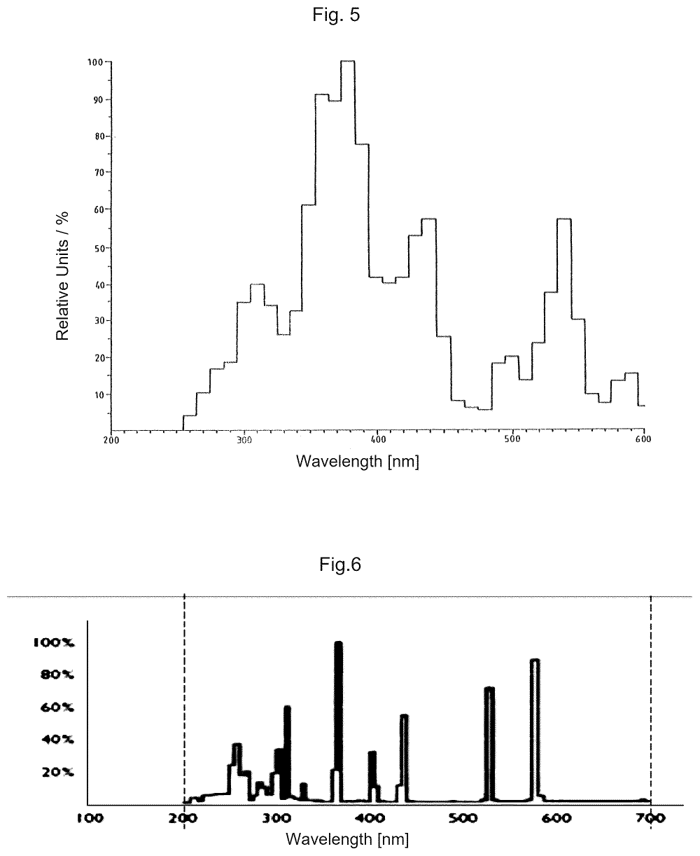

For the two glass compositions mentioned, solarization studies were additionally conducted for a frontside substrate having a thickness of 1 mm, with alternative employment of irradiation with a spectrum according to FIG. 5 for 7 hours. Here too, it was found that the transmittance curve and the intermediate transmittance Tₜᵣ=50% have a shift of less than 1 nm.

A further illustrative glass composition comprises the following components in percent by weight:

| | |
|---|---|
| SiO2 | 61.5-65.5 |
| Al2O3 | 1.8-4.5 |
| B2O3 | 8.5-10.5 |
| Na2O | 6.0-7.0 |
| K2O | 6.6-7.7 |
| ZnO | 6.0-8.5 |
| TiO2 | 3.0-4.0 |

A further illustrative glass composition comprises the following components in percent by weight:

| | |
|---|---|
| SiO₂ | 61-71 |
| Al₂O₃ | 5-8 |
| B₂O₃ | 9-14 |
| Na₂O | 9-10 |
| CaO | 2-3.5 |
| ZnO | 0-1 |
| TiO₂ | 0.0-6.0 |
| Sb₂O₃ | 0-1 |

and it is especially possible to provide a glass composition comprising the following components in percent by weight:

| | |
|---|---|
| SiO₂ | 62.4 |
| Al₂O₃ | 7.5 |
| B₂O₃ | 12.7 |
| Na₂O | 9.1 |
| CaO | 3 |
| ZnO | 0.8 |
| TiO₂ | 4 |
| Sb₂O₃ | 0.1 |

In particular, a glass composition as described above, but also a glass composition irrespective of the other components mentioned above, may comprise a proportion of titanium oxide in the range of 0-6, especially in the range of 3-5, for example 4. In addition, the glass composition, as an alternative or in addition to such a proportion or a proportion of titanium oxide mentioned in the table(s), may comprise a component that preferably acts as a UV absorber.

Useful examples include a proportion of one or more of the following components that are active with regard to UV absorption: cerium (for example in the form of CeO₂), antimony (for example in the form of Sb₂O₃), where an antimony content should preferably not exceed a proportion of 1 percent by weight, tin (for example in the form of SnO₂), niobium (for example in the form of Nb₂O₅), iron (in the form of Fe₂O₃), especially with an appropriately adjusted Fe²⁺/Fe³⁺ redox ratio.

Yet a further illustrative glass composition comprises the following proportions in percent by weight:

| | |
|---|---|
| SiO₂ | 58.0-59.5 |
| Al₂O₃ | 4.5-5.5 |
| B₂O₃ | 14.5-15.5 |
| K₂O | 9.5-10.5 |
| BaO | 9.5-10.5 |
| TiO₂ | 0.08-0.12 |
| CeO₂ | 0.5-1.5 |

Especially in the case of the illustrative glasses without cerium oxide, it is possible to keep the raw glass costs low, such that a frontside substrate having the properties mentioned is producible inexpensively. In association with a surface weight of below 500 g/m², for example below 300 g/m², it is thus possible to achieve a reduction both in the weight and in the costs of a solar module, and it is additionally possible, because of the intermediate transmittance, to achieve a suitable protective effect for components of the solar module, for example an adhesive layer, even under conditions of high UV radiation, as a result of which it is possible in turn to use less costly adhesive layers, so as to result overall in a potential for cost savings at several points and in a particularly suitable use for mobile applications, for example mobile devices, modes of transport, modes of transportation or manned or unmanned flying objects.

1-20. (canceled)

21. A frontside substrate for a solar module, wherein the frontside substrate has a surface weight of below 500 g/m², and wherein the frontside substrate comprises a material which, at a reference thickness of 100 μm, has a transmittance curve T(λ) that forms a transition from a lower transmittance T_{low} to an upper transmittance Tᵤₚ and has an intervening intermediate transmittance Tₜᵣ=50% in a wavelength range from 302 nm to 322 nm.

22. The frontside substrate of claim 21, wherein the frontside substrate has a surface weight of below 400 g/m², and/or wherein the intermediate transmittance Tₜᵣ=50% is in a wavelength range from 304 nm to 318 nm.

23. The frontside substrate of claim 21, wherein the frontside substrate has a thickness of less than 150 μm.

24. The frontside substrate of claim 21, wherein the transmittance curve T(λ) falls below a value of Tₜᵣ=10% at a wavelength in a wavelength range from 288 nm to 312 nm, and/or wherein the transmittance curve T(λ) rises above a value of Tₜᵣ=90% at a wavelength in a wavelength range from 322 nm to 400 nm.

25. The frontside substrate of claim 21, wherein the lower transmittance T_{low} is lower than 5%, and/or wherein the upper transmittance Tᵤₚ is greater than 85%.

26. The frontside substrate of claim 21, wherein the lower transmittance Tow is at a wavelength of at least 250 nm, and/or wherein the upper transmittance Tᵤₚ is at a wavelength of at most 375 nm.

27. The frontside substrate of claim 21, wherein the transmittance curve at at least one point has a slope of 2.8 percentage points/nm.

28. The frontside substrate of claim 21, wherein the transmittance curve after irradiation for 7 hours with light in a wavelength range from 250 nm to 600 nm has a shift of less than 5.0 nm, and/or wherein the transmittance curve after irradiation for 100 hours with UV-A light at 210 W/m², UV-B light at 170 W/m² and UV-C light at 250 W/m² has a shift of less than 5.0 nm.

29. The frontside substrate of claim 21, wherein at least one of the following is satisfied:
the material of the frontside substrate comprises a glass having a glass composition;
the glass is a borosilicate glass and the glass composition contains no Li₂O or contains Li₂O with a proportion of less than 50 ppm;
the glass composition contains no CaO or contains CaO with a proportion of less than 50 ppm;
the glass composition contains no MgO or contains MgO with a proportion of less than 50 ppm;
the glass composition contains no BaO or contains BaO with a proportion of less than 50 ppm;
the glass composition contains no SrO or contains SrO with a proportion of less than 50 ppm;
the glass composition contains no antimony (Sb) or contains antimony (Sb) with a proportion of less than 50 ppm; or
the glass composition contains no arsenic (As) or contains arsenic (As) with a proportion of less than 50 ppm.

30. The frontside substrate of claim 21, wherein the material of the frontside substrate comprises a borosilicate glass having a glass composition that does not contain any cerium oxide or contains cerium oxide with a proportion of less than 500 ppm.

31. The frontside substrate of claim 21, wherein the material of the frontside substrate comprises a glass having a glass composition and at least one of the following is satisfied:
the glass composition contains TiO₂ in a proportion of 0.5 to 10 percent by weight;
the glass composition contains Al₂O₃ in a proportion of 0 to 15 percent by weight;
the glass composition contains SiO₂ in a proportion of 30 to 80 percent by weight; or
the glass composition contains B₂O₃ in a proportion of 3 to 20 percent by weight.

32. The frontside substrate of claim 21, wherein the material of the frontside substrate has a density lower than 3.25 g/cm³.

33. The frontside substrate of claim 21, wherein the material of the frontside substrate has a modulus of elasticity higher than 68 GPa, and/or wherein the material of the frontside substrate has a modulus of elasticity lower than 78 GPa.

34. The frontside substrate of claim 21, wherein the material of the frontside substrate has a coefficient of thermal expansion in a temperature range from 20° C. to 300° C. of greater than 4×10⁻⁶ K⁻¹.

35. The frontside substrate of claim 21, wherein the frontside substrate has a dimension greater than 35 cm, and/or wherein the frontside substrate has a second dimension greater than 65 cm.

36. A frontside unit for a solar module, comprising:
a frontside substrate having a surface weight of below 500 g/m², wherein the frontside substrate comprises a material which, at a reference thickness of 100 μm, has a transmittance curve T(λ) that forms a transition from a lower transmittance T_{low} to an upper transmittance Tᵤₚ and has an intervening intermediate transmittance Tₜᵣ=50% in a wavelength range from 302 nm to 322 nm; and
an adhesive layer applied two-dimensionally atop the frontside substrate.

37. The frontside unit of claim 36, wherein the adhesive layer comprises at least one of the following materials: butyl polymer, EVA, PVB, silyl-modified polymer (SMP), or transparent silicone.

38. A solar module, comprising:
a frontside substrate having a surface weight of below 500 g/m², wherein the frontside substrate comprises a material which, at a reference thickness of 100 μm, has a transmittance curve T(λ) that forms a transition from a lower transmittance T_{low} to an upper transmittance Tᵤₚ and has an intervening intermediate transmittance Tₜᵣ=50% in a wavelength range from 302 nm to 322 nm;
a solar cell; and
an adhesive layer that bonds the frontside substrate to the solar cell.

39. The solar module of claim 38, further comprising a backside element, wherein the solar cell is disposed between the backside element and the frontside substrate.

40. The solar module of claim 38, wherein the backside element is in the form of a module frame.
